(19) United States
(12) Patent Application Publication
(10) Pub. No.: US 2006/0043291 A1
(43) Pub. Date: Mar. 2, 2006

(54) Electron spectroscopic metrology system

(76) Inventor: Gang Grant Peng, Fremont, CA (US)

Correspondence Address: GANG GRANT PENG, 32 MISSION CIELO AVE, FREMONT, CA, 94539, US

(21) Appl. No.: 10/927,410

(22) Filed: Aug. 26, 2004

(51) Int. Cl. G01N 23/20; H01J 37/28

(52) U.S. Cl. 250/310; 250/307

(57) ABSTRACT

The present invention discloses a new electron spectroscopic metrology system using an electron beam to measure the periodic feature on a substrate. The present invention provides a measurement system for the geometry parameters of the periodic feature which is only a few repeating small elements in the measurement area. The present invention has the following advantages: (1) capable of measuring a small feature of an array of lines (line width less than a couple of ten nanometers); (2) capable of measuring a small feature of an array of via holes; (3) capable of measuring an isolated feature, with a line and patch ratio less than 1:10; (4) capable of measuring a small area, less than twenty five square micrometers; (5) no need to input detailed knowledge about the feature and its film stack; (6) simple theoretical model to derive the geometry parameters. The total simplicity of the present invention will enhance the electron spectroscopic metrology system's overall performance and productivity.

### BACKGROUND OF THE INVENTION

(1) Field of the Invention

The present invention relates to the field of metrology monitoring and process controlling of wafer fabrication processes, especially the photolithography and etching processes.

(2) Prior Art

The general way to monitor the wafer fabrication processes is by using a critical dimension scan electron microscope (CDSEM). The CDSEM generates an image from the electron intensity profile of the line-scan of the probe electron beam at the viewing area. Different topography and materials will have different electron deflection and second electron yields. The detector collects all the electrons available from the specimen during the line-scan, pixel by pixel, regardless of the energies of these electrons. The CD measurement can be taken either on the apparent feature on the image constructed from the line scanning or on the line scan itself The major limitations for the CDSEM are the less geometric resolution due to the large interaction volume, the low contrast, and most of the time, edge glowing and/or blurring. To reduce the limitations due to the large interaction volume and edge glowing, the acceleration energy of the probing electron beam is drastically reduced. Different coating techniques have been explored to enhance the contrast for current available materials, which either have the small atomic number, Z, for low −k dielectric materials or close atomic numbers for adjacent layers, such as a thin layer of silicon nitride or silicon oxide with polycrystalline silicon. People have been working on techniques to improve the CDSEM measurement, for example Tanaka et al in U.S. Pat. No. 6,706,543. Houge et al also proposed the multiple parameter characterization (MPC) algorithms to improve the CDSEM measurement mathematically in U.S. Pat. No. 6,714,892. But the nature of the CDSEM based metrology remains the same and its basic limitations are still a hurdle for metrology measurements requiring high precision and better repeatability.

In recent years, optical CD measurement tools, such as Spectroscopic CD (SCD) or Optical Profilometry (OP) have been developed as alternatives for the CD measurement. The optical spectroscopic CD techniques are mainly based on the UV-Vis light interference of the grating like feature on a substrate. The optical CD techniques measure the reflection and/or the phase changes between different polarizations of light as a function of the wavelength or the angle that is between the incident light and the detected light. There are mainly three different types of optical CD tools: (1) varying incident angle profilometry, angle-resolved scatterometer by Acct Optical Technologies Inc partially in U.S. Pat. No. 6,606,152; (2) spectroscopic ellipsometer by KLA-Tencor Technologies Corp. in U.S. Pat. No. 6,590,656 and Timbre Technologies Inc. in U.S. Pat. No. 6,645,824, and (3) the spectroscopic profilometry by Novo Measuring Instruments Ltd. in U.S. Pat. No. 6,704,920. The light source for the optical CD tools are in the range of UV-Vis (190 nm to 800 nm) and the angle-resolved scatterometer uses a single wavelength laser in UV-Vis range. As the size of the semiconductor devices continues to decrease to 25 nm, the interference from UV-Vis optical scatterometer losses its sensitivity drastically. The UV-Vis light scatterometer applications are limited to an array of dense lines only, not for via holes or trenches, due to its limited resolution power. The other fundamental limitations of the UV-Vis light scatterometer are that a) it requires a relatively large area (2500 square micrometers); b) a special manufactured periodic feature on the substrate for the measurement; and c) detail knowledge of the feature and associated film structures.

### BRIEF SUMMARY OF THE INVENTION

In primary aspect, the present invention discloses a new type of electron spectroscope metrology system that uses an electron spectroscopic scattering technique to measure a periodic feature on a substrate during IC fabrication processes, such as lithography and etch processes. The electron spectroscope metrology system of the present invention is an energy-resolved metrology system, which provides a method to perform the diffraction measurement with an electron beam having a wavelength much shorter than the size of the periodic feature on the substrate. The electron spectroscopic scattering technique collects the electron intensity over a range of wavelength and yields the information of the periodic feature only from the very top surface of the feature due to electron nanometer level escaping depth. The present invention further derives the geometry parameters from said electron spectroscopic scattering spectra. The geometry parameters of the periodic feature include, a) the pitch that is the sum of the width of the repeating element; b) the critical dimensions (CD) that is the line width of the element at certain z height; and c) the side wall angle of the line.

Because of its nature of using an electron beam and doing the electron scattering spectroscopy, the present invention has the following advantages.
a) The present invention provides the necessary sensitivity and control-ability to measure a small area of several square micrometers.
b) The present invention provides said measurement for small size of the periodic feature, for an array of lines, the line width being equal or less than a couple of ten nanometers.
c) The present invention provides the measurement for small size of the periodic feature, for an array of via holes or of trenches.
d) The present invention provides the measurement for small size of the periodic feature, for an array of via holes or of trenches.
e) The present invention provides the measurement for a fewer feature in the measurement area, isolated feature.
f) The present invention produces the chemical elemental information during said measurement, opposite to the optical scatterometer techniques that require the detail knowledge about the feature and materials prior to a measurement, provides the chemical elemental information of the periodic feature or film.

In another aspect, the present invention provides the apparatus of the electron spectroscope metrology system that measures a periodic feature on a substrate during IC fabrication processes. Said apparatus includes:
a) an electron source which emits the electron beam at a selected energy within a range of beam energies;
b) a means of electron detection which collects the reflection and diffraction electrons from the periodic feature to build a scan electron microscope image.
c) a means of electron spectroscopic analyzer which collects the diffracting electrons from said periodic feature over an energy range. The angle between the electron beam and the electron spectroscopic analyzer is fixed.
d) an algorithm to calculate the geometry parameters by comparing the measurement spectrum to the theoretical models.
e) a stage to hold and move the substrate during said measurement process; a means of stage and substrate alignment such as pattern recognition device which aligns the measurement feature and the substrate to pre-selected periodic feature;
f) a vacuum chamber to keep the substrate, electron source, electron detection and analyzer devices, and stage under vacuum.

In further aspect, the present invention discloses a new type of electron spectroscope metrology system that uses an electron spectroscopic scattering spectrum with angle-resolved technique to measure a periodic feature on a substrate during IC fabrication processes. Said angle-resolved electron spectroscopic scattering spectroscopy collects the electron intensity over a range of angle that is defined as the angle between the electron beam and the detection beam of the electron spectroscopic analyzer and it yields similar information regarding the feature geometry as said energy-resolved electron spectroscopic scattering spectroscopy. Said angle-resolved electron spectroscopic scattering spectroscopy in the present invention further derives the geometry parameters using a theoretical model different from said energy-resolved electron spectroscopic scattering spectroscopy.

Said angle-resolved electron spectroscopic scattering spectroscopy of the present invention has similar advantages as said energy-resolved electron spectroscopic scattering spectroscopy.

In another aspect, the present invention provides the apparatus of said angle-resolved electron spectroscope metrology system, including different means than said energy-resolved electron spectroscope metrology system:
a) an electron source which emits the electron beam at a selected energy;
b) a means of the electron spectroscopic analyzer which collects the diffracting electrons from said periodic feature over a range of angles.
c) a means of varying the angle between said electron beam and the electron spectroscopic analyzer.
d) an algorithm to calculate the geometry parameters by comparing the measurement spectrum to the theoretical models.

In further aspect, the present invention discloses a new type of electron spectroscope metrology system that uses an electron spectroscopic scattering spectrum with both energy-resolved and angle-resolved technique to measure a periodic feature on a substrate. Said energy-resolved and angle-resolved electron spectroscopic scattering spectroscopy collects the electron intensity over a range of energy and over a range of angle separately. Said energy-resolved and angle-resolved electron spectroscopic scattering spectroscopy in the present invention further derives the geometry parameters using a theoretical model combining both said energy-resolved and said angle-resolved electron spectroscopic scattering spectroscopes.

In another aspect, the present invention provides the apparatus of said energy-resolved and angle-resolved electron spectroscope metrology system, comprising:
a) an electron source which emits the electron beam at a selected energy;
b) a means of the electron spectroscopic analyzer which collects the diffracting electrons from said periodic feature over an energy range.
c) a means of varying the angle between said electron beam and the electron spectroscopic analyzer.

In an additional aspect, the present invention provides additional means for loading and unloading said substrate and substrate pr-alignment, including the cassette stations; the loading and unloading mechanism; the substrate pre-alignment device.

Further objects and advantages of the present invention will become apparent from a consideration of the following description and drawings.

### BRIEF DESCRIPTION OF THE SEVERAL VIEWS OF DRAWINGS

The novel features believed characteristic of the present invention are set forth in the claims. The invention itself, as well as other features and advantages thereof will be best understood by referring to detailed descriptions that follow and when read in conjunction with the accompanying drawings.

Reference is specifically made to the drawings wherein like numbers are used to designate like members throughout.

FIG. 1a is a schematic drawing of a UV-Vis spectroscopic scatterometer of prior art.

FIG. 1b is a schematic drawing of a varying angle UV-Vis scatterometer of prior art.

FIG. 2a-2d show the embodiments of the cross section view and the top down view of the periodic feature of the present invention.

FIG. 2a is a cross sectional view of the periodic feature of an array of lines on a substrate.

FIG. 2b is a top down view of the periodic feature shown in FIG. 2a.

FIG. 2c is a top down view of the periodic feature of an array of via holes on a substrate.

FIG. 2d is a top down view of the periodic feature of an array of trench on a substrate.

FIG. 3 is a schematic of the preferred electron spectroscopic metrology system having the electron beam from the electron source with a SEM electron detector, and an electron spectroscopic analyzer aligned, combined with a substrate loading and unloading system of the present invention.

FIG. 4 is a schematic of the preferred electron spectroscopic metrology system with an electron spectroscopic analyzer separated from the electron source, combined with the substrate loading and unloading system.

FIG. 5a-5c are graphical representations of the electron spectroscopic scattering spectrum for periodic feature of an array of lines by the preferred electron spectroscopic metrology system of the present invention. The measurement spectra are taken with the incident angle of the electron beam perpendicular to said feature.

FIG. 5a is a graphical representation of the electron spectroscopic scattering spectrum for an array of dense lines on a substrate by the preferred electron spectroscopic metrology system of the present invention. The measurement is assumed with the electron beam perpendicular to said array of isolated lines.

FIG. 5b is graphical representation of the electron spectroscopic scattering spectrum on an array of dense lines on a substrate by the preferred electron spectroscopic metrology system of the present invention. The measurement is taken with the electron beam parallel to said array of dense lines.

FIG. 5c is graphical representation of the electron spectroscopic scattering spectrum on an array of isolated lines on a substrate by the preferred electron spectroscopic metrology system of the present invention. The measurement is assumed with the electron beam perpendicular to said array of isolated lines.

### DETAILED DESCRIPTION OF THE INVENTION

While preferred embodiments of the present invention will be described below, those skilled in the art will recognize that other hardware configurations including the electron beam from said electron source, the scan electron microscope (SEM) electron detector, the electron spectroscopic analyzer, the stage, and the substrate loading and unloading system, are capable of implementing the principles of the present invention. Thus the following description is illustrative only and not limiting.

Reference is specifically made to the drawings wherein like numbers are used to designate like members throughout.

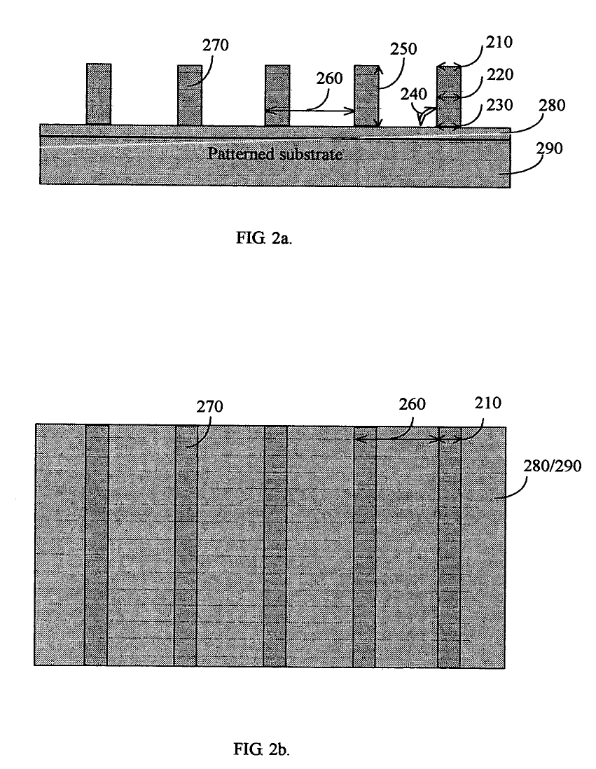

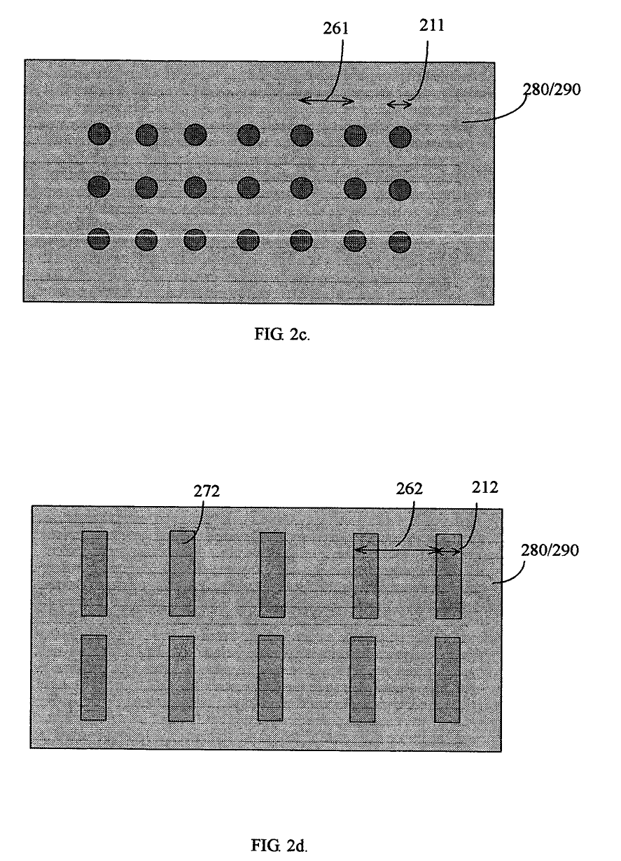

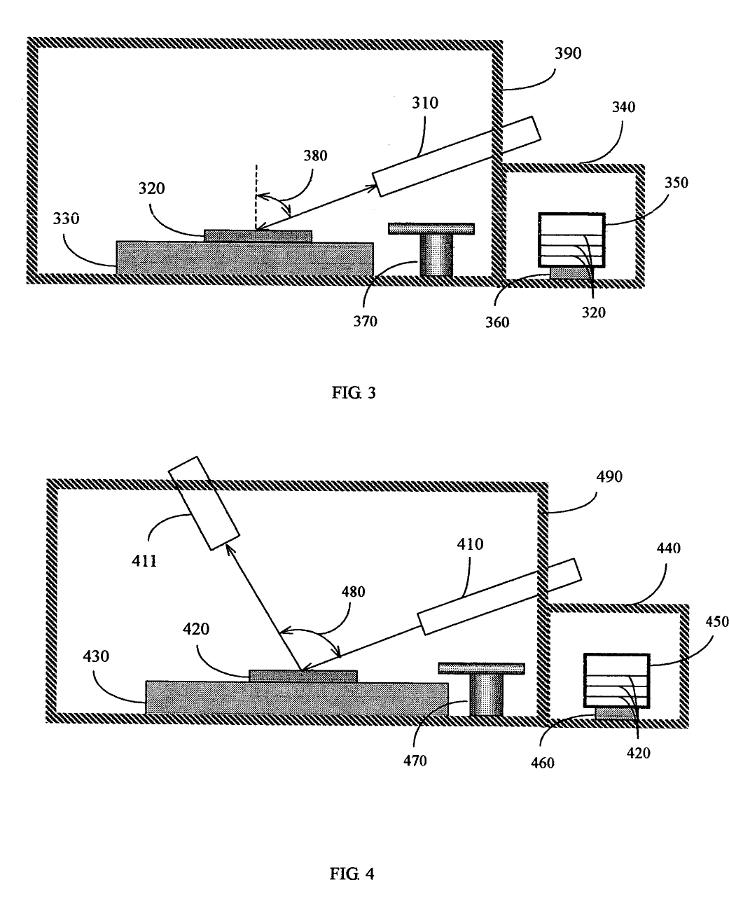

Note the followings:
(1) The dimensions of all of drawings are not to scale.
(2) The normal direction of the sample is equivalent to the oblique angle of zero degree.
(3) The capabilities of the scan electron microscope image and pattern searching and substrate alignment of the present invention are available for all the configurations in drawings FIG. 3 and FIG. 4.
(4) The electron spectroscopic analyzer in the different configurations, FIG. 3 and FIG. 4, of the present invention can be the same or different.
(5) The substrate, the film stack, and the periodic feature in drawings FIG. 3 and FIG. 4 are used as the same to illustrate the principle and functionality of the present invention.
(6) The substrate may be of either silicon or germanium or other materials.
(7) The array of lines as embodiments of the present invention is illustrated in FIG. 2. However said electron spectroscopic metrology system measurement is applicable to other type of periodic patterns, such as an array of contact via holes.
(8) The array with non-flat topography feature as embodiments of the present invention is illustrated in the FIG. 2 and FIG. 4. However the present invention is applicable to the flat topography features that have periodic patterns made by different material.
(9) The stage, the robot, the cassette station, and the cassette in the drawing FIG. 3 and FIG. 4 can be the same or different for each configuration and system.

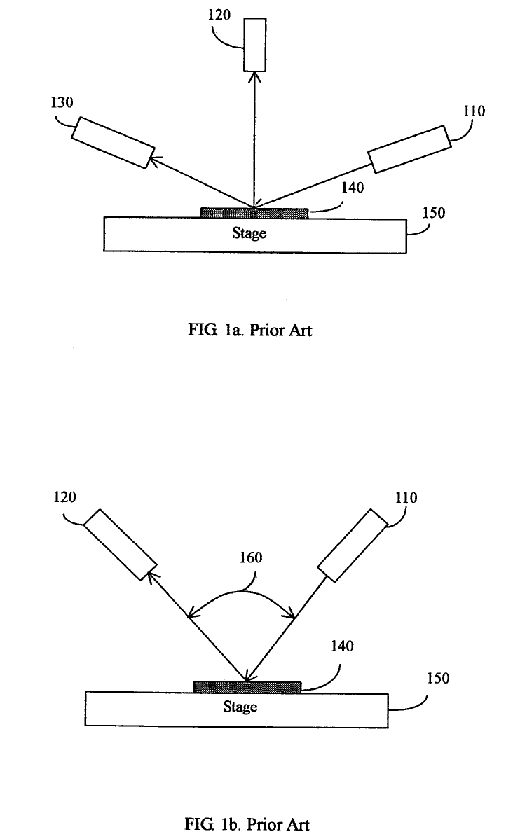

FIG. 1a is a cross sectional view of prior art of the UV-Vis optical scatterometer. The UV-Vis optical scatterometer with many variations is the main technique nowadays for optical CD measurement. The stage 150 moves the substrate to a certain location precisely so that the UV-Vis light 110 will illuminate on the pre selected pattern on the surface of said substrate 140. Normally the UV-Vis light sources have the wavelength range of 180 nm to 780 nm. The spectroscopic ellipsometer photon detector 130 detects the light from the periodic feature and generates the ellipsometry spectra. The photon detector 120 detects the reflection intensity of the light and the resulted reflectometer spectrum can be used to produce the film information, the thickness of the film (s) on the substrate surface and optical index. The geometry information of the periodic feature can be generated from the ellipsometry spectra with the additional film information from said reflectometer spectrum.

FIG. 1b is a cross sectional view of a prior art of typical varying angle scatterometer. A varying angle scatterometer uses either a single wavelength light source 110 or a multiple wavelength light sources, not shown. A reflection detector 120 detects the reflection intensity as the angle 160 sequentially varies over a range, which results in the angle-resolved scattering spectrum. The parameters of the periodic feature can be calculated from said angle-resolved scattering spectrum. The stage 150 moves the substrate 140 to a measurement area precisely for measurement. Like the other types of optical CD techniques, the varying angle scatterometer technique requires the inputs of film thickness and optical index in order to calculate the geometry parameters.

FIGS. 2a and 2b are the cross sectional view and top down view of a periodic feature 270 on substrate 290 respectively, which will be used as embodiment in the present invention. There are three CDs, the top CD 210, the middle CD 220, the bottom CD 230, the side wall angle 240 and the feature height 250. The pitch 260 and the CD (s) define the periodic property of said periodic feature. The periodic feature 270 may be made of a film stack with different materials and different thickness. The side wall angle 240 and the height 250 of the feature are important for determining the overall cross section profile. There may be film (s) 280 between substrate 290 and periodic feature 270. Unlike the other techniques in the prior arts, the electron spectroscopic metrology system of the present invention does not require film information for neither 270 nor 280 for deriving the parameters of the periodic feature.

FIG. 2c is a top down view of the array of via holes with diameter 211 and pitch 261 that can be measured by the electron spectroscopic metrology system of the present invention.

FIG. 2d is a top down view of the array of trenches with CD 212 and pitch 262 that can be measured by the electron spectroscopic metrology system of the present invention.

FIG. 3 is a cross section view of the embodiment of the present invention. The electron spectroscopic metrology system 390 of the present invention operates under vacuum. The electron source, the scan electron microscope (SEM) electron detector, and the electron spectroscopic analyzer are assembled together as part of 310. The electron source produces an electron beam at certain energy level ranging from 1 kV to 20 kV and at a certain angle 380 relative to the periodic feature. The electron beam excites a large amount of Auger electrons and scattered electrons from the periodic feature 270. The SEM electron detector 310 collects the second electrons and generates SEM image. The electron spectroscopic analyzer 310 detects the scattered electrons and the Auger electrons simultaneously. The incident angle 380 of said electron beam from said electron source and the electron spectroscopic analyzer 310 is fixed to a predetermined angle in order to maxim the emitted electrons.

The embodiment of the electron spectroscopic metrology system 390 in the present invention uses energy scan with a fixed angle, φ₀, between the incident beam and the periodic feature 270. The angle, φ₀, is selected for the maxim scattering electrons and minimum background. Then, the scattered electron intensity vs. the emitted electron energy, E, is recorded as the energy-resolved spectroscopic scattering spectrum, I(E, φ₀).

The wavelength of the electron beam is significantly shorter than the feature size, less than one nanometer vs. tens of nanometers, respectively. Shorter wavelength of the probing electron beam will simplify the theoretic model used to derive the geometry parameters of the periodic feature from the electron spectroscopic scattering spectrum. The nature of the high lateral resolution of electron beam technique enables the embodiment of the present invention to precisely define a much smaller measurement area with fewer and smaller periodic features compared to the UV-Vis optical scatterometer techniques.

The embodiment of the present invention applies its image processing capability to navigate the stage 330 to a pre defined measurement area and to identify the measurement pattern, such as 270. Then the stage 330 carries substrate 320 to the precise position and aligns the feature 270 exactly for future scattering measurement.

The embodiment of said electron spectroscopic metrology system 390 in the present invention combining with a substrate loading and unloading device 340, which includes a substrate cassette 350, a robot 370, and a cassette station 360. The robot 370 transfers the substrate(s) 320 between the cassette 350 and the stage 330.

There may have a substrate pre-aligner in the electron spectroscopic metrology system 390, which aligns the substrate to a precise orientation before said substrate being transferred into the electron spectroscopic metrology system 390. The robot 370 will transfer the substrate(s) 320 between the cassette 350 and the pre-aligner and said stage 330. Said substrate pre-aligner is not shown in both FIG. 3 and FIG. 4.

FIG. 4 is a cross section view of the embodiment of the present invention. The electron spectroscopic metrology system 490 of the present invention operates under vacuum. The electron beam from the electron source and second electron detector 410 is separated from the spectroscopic electron spectroscopic analyzer 411. There are two major versions of configurations of the present invention, the single energy angle-resolved type, I(E₀, φ) and the multi energy angle-resolved type, I(E_{I}, φ).
A) Said single energy angle-resolved type uses a fixed collection energy, E₀, for the analyzer 411 and collects the electron intensity vs. said angle 480, φ, that varies over a certain angle range.
B) Said multiple energy angle-resolved type collects the electron intensity against the energy, E_{I}, and said angle 480, φ, which generates a 3-dimensional spectrum, I(E_{I}, φ).

The interpretation of the electron spectroscopic scattering spectrum and the calculation of the geometry for the periodic feature will be different for the two types of configurations.

The electron source produces an electron beam in the energy range of 1 kV to 20 kV, which excites a large amount of scattered electrons and Auger electrons from the periodic feature 270. The electron spectroscopic analyzer 411 detects said scattered electrons and said Auger electrons over a collecting energy range. The embodiment of the present invention has image processing capability to navigate the stage 430 and to align the substrate 420 to the precise position for the scattering measurement.

The electron spectroscopic metrology system 490 in the present invention has a substrate loading and unloading device 440 and a robot 470. The robot 470 transfers the substrate(s) 420 between the cassette 450 and the stage 430. A substrate pre-aligner may also be used in the electron spectroscopic metrology system 390, which aligns the substrate to a precise orientation before loading said substrate into the electron spectroscopic metrology system 390. Then, the robot 370 will transfer the substrate(s) 320 between the cassette 350 and said pre-aligner and the stage 330.

The selection of configuration of the present invention depends on the specific requirements for the given applications.

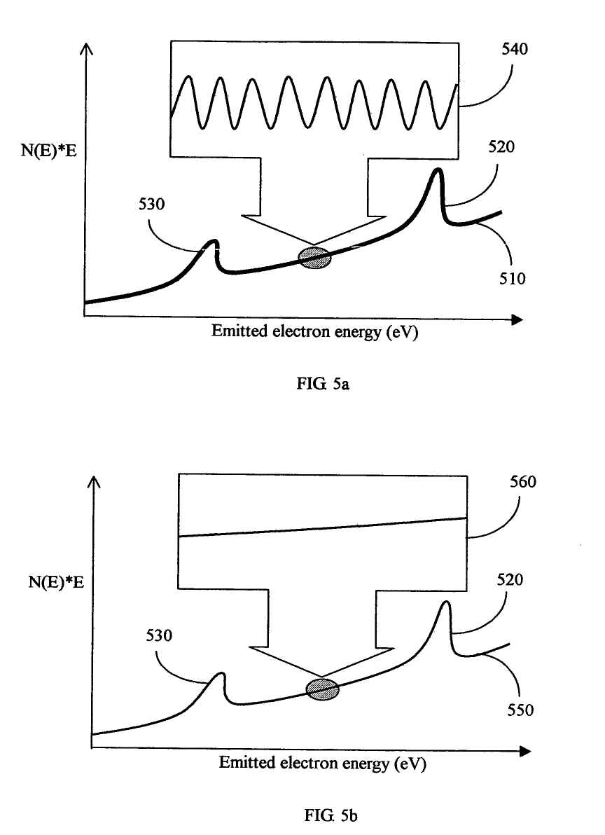

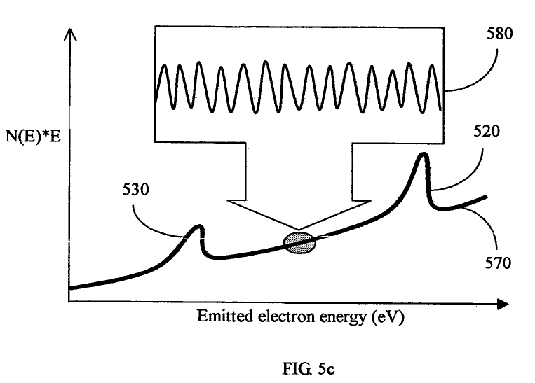

FIG. 5a is the graphical drawing of the electron spectroscopic scattering spectrum 510 generated by the energy-resolved electron spectroscopic metrology system of the present invention. The electron scattering spectrum 510 is generated with the incident electron beam perpendicular to the lines in the array of dense lines, the line to patch ratio of 1:2. There are Auger electron peaks 520 and 530 that are characteristic to certain chemical elements and the ratio of the peaks proportional to the material's atomic composition. The scattered electrons are slowly changing and featureless. The zoom-in spectrum 540 shows the diffraction interference due to the geometry of the array of dense lines. The geometry parameters of said lines can be obtained from the diffraction interference by using the preferred software system in the present invention.

FIG. 5b is the graphical drawing of the electron spectroscopic scattering spectrum 550 generated by the energy-resolved electron spectroscopic metrology system of the present invention. The spectrum 550 is generated for said array of dense lines as in FIG. 5a, but the incident electron beam parallel to the lines of said array of dense lines. The Auger peaks 520 and 530 remains the same as in FIG. 5a. The zoom-in spectrum 560 shows no diffraction interference because of the relative orientation of said incident electron beam to said lines of the array. The spectrum 550 will be used as the background for the scatterometer measurement. To simplify the calculation of the geometry of the periodic feature, the background spectrum 550 can be subtracted from the spectrum 510.

FIG. 5c is the graphical drawing of the electron spectroscopic scattering spectrum 570 generated by the energy-resolved electron spectroscopic metrology system of the present invention. The electron scattering spectrum 570 is generated with the incident electron beam perpendicular to the lines of the array of the isolated lines, the line to patch ratio of 1:10. The extreme short escape length of the electrons gives the embodiment of the present invention sufficient surface sensitivity to measure only a few lines of the array of isolated lines compared to a few tens of lines required by the UV-Vis optical scatterometer technologies. The Auger electron peaks 520 and 530 remains the same as that in FIGS. 5a and 5b, because of the identical film stack of the feature and neglecting the shadow effect. The zoom-in spectrum 580 shows a different diffraction interference due to the change of the line density.

Although the description above contains specifications, these should not be construed as limiting the scope of the present invention but as merely providing illustrations of some of the presently preferred embodiments of the present invention. Therefore the scope of the present invention should be determined by the claims and their legal equivalents, rather than by the examples given.

Claims:

What we claim are:

1. An apparatus for metrology measurement of a periodic periodic feature on a substrate, said metrology measurement comprising feature widths, height, side wall angle, and pitch, comprising:
an electron source to generate electron beam;
an scan electron microscope detector to detect the second electrons for scan electron microscope image;
a stage holding said substrate and moving said substrate precisely;
an electron spectroscopic analyzer to record the electron spectroscopic scattering spectrum;
a processor to derive said periodic feature parameters from said electron spectroscopic scattering spectra;

2. An apparatus of claim 1, wherein said electron source contains means to generate said electron beam at an oblique angle relative to said periodic feature.

3. An apparatus of claim 1, wherein said electron source contains means to emit said electron beam over an energy range.

4. An apparatus of claim 1, wherein said scan electron microscope detector detects second electrons from said periodic feature to construct a scan electron microscope image.

5. An apparatus of claim 1, wherein said electron spectroscopic analyzer is fixed at an angle relative to said electron beam from said electron source.

6. An apparatus of claim 5, further including said electron spectroscopic analyzer having a zero degree angle relative to said electron beam when said electron spectroscopic analyzer aligns with said electron beam.

7. A process of claim 1, wherein said collecting said electron spectroscopic scattering spectrum on said periodic feature with said electron beam perpendicular to said periodic feature.

8. A process of claim 1, wherein said collecting the background electron spectroscopic scattering spectrum on said periodic feature with said electron beam parallel to said periodic feature.

9. A process of claim 1, wherein said one or more parameters comprising line width, pitch, height, and side wall angle of said periodic feature.

10. A method for metrology measurement of one or more parameters for a periodic feature on a substrate, said parameters comprising feature widths, height, side wall angle, and pitch, said method comprising:
directing the electron beam towards said periodic feature;
aligning said periodic feature exactly;
detecting the intensity of the Auger electron and the scattering electron from said periodic feature;
recording an electron spectroscopic scattering spectrum;
determine one or more parameters of said periodic feature by comparing said electron spectroscopic scattering spectrum to a theoretical model.

11. The method of claim 10, wherein said directing controls said electron beam at a landing energy in the energy range of 100V to 20 kV.

12. The method of claim 10, wherein said directing makes said electron beam having an angle relative to said electron spectroscopic detector.

13. The method of claim 12, further including zero degree of said angle when said electron beam aligns to said electron spectroscopic analyzer.

14. The method of claim 10, wherein said aligning compares the scan electron microscope images, comprising:
detecting the intensity of the second electrons from said periodic feature;
constructing said scan electron microscope image from said intensity of second electron;
guiding a pattern search process.

15. The method in claim 14, wherein said guiding a pattern search comprises:
moving to the predicated targeting area;
comparing concurrent said scan electron microscope image to said pre selected periodic feature;
moving said substrate around step by step and comparing said concurrent scan electron microscope image to said pre selected periodic feature after each step of said moving until the concurrently scan electron microscope image matching to said pre selected periodic feature.

16. The method in claim 10, wherein said detecting by using said electron spectroscopic analyzer to detect the intensity of said Auger electron and scatter electrons over an energy range of the emitted electrons.

17. The method in claim 10, wherein said recording comprises:
collecting an electron spectroscopic scattering spectrum of said periodic feature by orientating said periodic feature perpendicular to said spectroscopic electron detector,
collecting a background electron spectroscopic scattering spectrum by orientating said periodic feature parallel to said spectroscopic electron detector.

18. The method in claim 10, wherein said determining compares the intensity data of a net electron spectroscopic scattering spectrum at certain energy range to a portion of said theoretical model.

19. The method in claim 18, wherein said net electron spectroscopic scattering spectrum is generated by subtracting said background electron spectroscopic scattering spectrum from said electron spectroscopic scattering spectrum.

20. The method in claim 10, wherein said determining uses said theoretical model with one or more parameters of the periodic feature, comprising said feature widths, height, side wall angle, and pitch of said periodic feature on said substrate during substrate fabrication monitoring or controlling process.

21. An apparatus for metrology measurement of a periodic feature of a sample, said metrology measurement comprising feature widths, height, side wall angle, and pitch, comprising:
an electron source generating electron beam;
an electron detector detecting the second electrons for scan electron microscope image;
a stage holding the substrate and moving said substrate precisely;
an electron spectroscopic analyzer recording the raw spectrum;
a processor deriving said one or more parameters of said periodic feature from said net electron spectroscopic scattering spectrum.

22. An apparatus of claim 21, wherein either said electron beam generated by said electron source or said electron spectroscopic analyzer is at the normal direction of said sample.

23. An apparatus of claim 22, further including having a non-zero angle between said electron beam and said electron spectroscopic analyzer.

24. An apparatus for metrology measurement of a periodic periodic feature of a sample by varying the angle between said electron beam and said electron spectroscopic analyzer, said metrology measurement comprising feature widths, height, side wall angle, and pitch, comprising:
an electron source generating electron beam;
a detector detecting the second electrons for scan electron microscope imaging;
a stage holding the substrate and moving said substrate precisely;
an electron spectroscopic analyzer recording said angle-resolved electron scattering spectrum;
a processor deriving said periodic feature parameters from said net electron energy-resolved scattering spectrum;

25. An apparatus of claim 24, wherein said electron beam has a non-zero angle relative to said electron spectroscopic analyzer.

26. An apparatus of claim 25, wherein said angle between said electron beam and said electron spectroscopic analyzer can vary over a range of angles.

27. An apparatus of claim 26, wherein said angle between said electron beam and said electron spectroscopic analyzer is sequentially changed step by step from one end of said angle range to the other end of said angle range.

28. An apparatus of claim 24, wherein said recording angle-resolved electron scattering spectrum records the intensity of Auger electron and scattering electron from said periodic feature as a function of varying angles.

29. A process of claim 24, wherein said collecting angle-resolved electron scattering spectrum on said periodic feature by applying said electron beam perpendicular to said periodic feature.

30. A process of claim 24, wherein said collecting angle-resolved electron scattering spectrum of the background on said periodic feature by applying said electron beam parallel to said periodic feature.

31. A process of claim 24, wherein said one or more parameters comprising line width, pitch, height, and side wall angle of said periodic feature.

32. A method for metrology measuring one or more parameters for a periodic periodic feature of a sample, said parameters comprising feature widths, height, side wall angle, and pitch, said method comprising:
directing the electron beam towards the periodic feature;
aligning said periodic feature exactly based on scan electron microscope image;
detecting the intensity of the Auger electron and the scattering electron;
generating an angle-resolved electron scattering spectrum;
comparing said angle-resolved electron scattering spectrum to a theoretical model to determine one or more parameters of said periodic feature.

33. The method of claim 32, wherein said directing directs said electron beam towards said periodic feature with an angle relative to said electron spectroscopic analyzer.

34. The method in claim 32, wherein said detecting comprises collecting the intensity of said Auger electron and scatter electron from said periodic feature as a function of said varying angle.

35. The method in claim 34, wherein said collecting uses said electron beam at a fixed energy.

36. The method in claim 32, wherein said generating an angle-resolved scattering spectrum records said intensity of Auger electron and scatter electron at one or multiple emitted energies as a function of said varying angle by orientating said electron beam perpendicular to said periodic feature.

37. The method in claim 32, wherein said generating an angle-resolved scattering spectrum of the background records said intensity of Auger electron and scatter electron at one or multiple emitted energies as a function of said varying angle while orientating said electron beam parallel to said periodic feature.

38. The method in claim 32, wherein said generating generates a net angle-resolved scattering spectrum at one or multiple energies by subtracting said angle-resolved scattering spectrum of the background from said angle-resolved scattering spectrum of said periodic feature.

39. The method in claim 32, wherein said comparing uses said theoretical model with one or more parameters of the periodic feature, comprising said feature widths, height, side wall angle, and pitch of the periodic feature.
